(19) United States
(12) Patent Application Publication
(10) Pub. No.: US 2025/0380348 A1
(43) Pub. Date: Dec. 11, 2025

(54) LIGHT SOURCE APPARATUS AND METHOD FOR CONTROLLING LIGHT SOURCE APPARATUS

(71) Applicant: Lasertec Corporation, Yokohama (JP)

(72) Inventors: Karl Joel HALLBAECK, Yokohama-shi (JP); Keitaro HAYASHIDA, Yokohama-shi (JP); Masayasu NISHIZAWA, Yokohama-shi (JP); Masaki INOUE, Yokohama-shi (JP); Takahide TAKAMATSU, Yokohama-shi (JP)

(21) Appl. No.: 19/229,472

(22) Filed: Jun. 5, 2025

(30) Foreign Application Priority Data
Jun. 6, 2024 (JP) 2024-092286

(51) Int. Cl. H05G 2/00; G03F 7/00

(52) U.S. Cl. CPC H05G 2/0027; G03F 7/70033; H05G 2/003; H05G 2/0084

(57) ABSTRACT

A light source apparatus according to the present disclosure includes: a target holding unit having a holding surface for holding a target material for generating light; and an acquisition unit configured to acquire state information of the holding surface, in which the holding surface includes a first region and a second region, a depth of the first region from a predetermined surface is greater than that of the second region, the target material is held in the first region when the amount of the target material is a first amount, the target material is held in the first region and the second region when the amount of the target material is a second amount greater than the first amount, and the acquisition unit acquires the amount of the target material based on a region in which the target material occupies the holding surface in the acquired state information.

### INCORPORATION BY REFERENCE

This application is based upon and claims the benefit of priority from Japanese patent application No. 2024-092286, filed on Jun. 6, 2024, the disclosure of which is incorporated herein in its entirety by reference for all purposes.

### BACKGROUND

The present disclosure relates to a light source apparatus and a method for controlling a light source apparatus.

Patent Literature 1 describes a light source apparatus in which a target material is formed on a surface of a cylindrical member rotating around a rotational axis and which irradiates the formed target material with excitation light, thereby extracting illumination light.

Patent Literature 2 describes a light source apparatus that holds, by a centrifugal force, a liquid target material on an inner wall of a crucible rotating around a rotational axis, and irradiates the held target material with excitation light, thereby extracting illumination light.
[Patent Literature 1] Japanese Unexamined Patent Application Publication No. 2020-077007
[Patent Literature 2] Japanese Unexamined Patent Application Publication No. 2022-168463

### SUMMARY

When a target material for generating light is held by a target holding unit such as a cylindrical member and a crucible in the light source apparatus, the amount of the target material is changed in accordance with consumption by generation of light and supply from a supply unit. It is desired to easily acquire the amount of the target material held in the target holding unit in order to stably extract illumination light.

The present disclosure has been made to solve such a problem, and an object of the present disclosure is to provide a light source apparatus and a method for controlling a light source apparatus capable of easily acquiring an amount of a target material.

A light source apparatus according to the present disclosure includes: a target holding unit having a holding surface that holds a target material for generating light; an acquisition unit configured to acquire state information of the holding surface; and a processing unit configured to acquire an amount of the target material based on the state information, in which the holding surface includes a first region and a second region, a depth of the first region from a predetermined surface is greater than that of the second region, the target material is held in the first region when the amount of the target material is a first amount, the target material is held in the first region and the second region when the amount of the target material is a second amount which is greater than the first amount, and the processing unit acquires the amount of the target material based on a region in which the target material occupies the holding surface in the acquired state information.

In the aforementioned light source apparatus, the holding surface may further include a third region, a depth of the second region from the predetermined surface is greater than that of the third region, and the target material may be held in the first region, the second region, and the third region when the amount of the target material is a third amount which is greater than the second amount.

In the aforementioned light source apparatus, the processing unit may acquire the amount of the target material based on at least one of a width and an area of a region in which the target material covers the holding surface.

In the aforementioned light source apparatus, the acquisition unit may include a camera, the acquisition unit acquires image information of the holding surface imaged by the camera as the state information of the holding surface, and the processing unit may acquire the amount of the target material based on a region in which the target material occupies the holding surface identified in the image information.

The aforementioned light source apparatus may further include a formation unit including a condenser lens that focuses excitation light forming plasma by exciting the target material on the target material, and the camera may image the holding surface via the condenser lens.

In the aforementioned light source apparatus, the acquisition unit may further include a displacement meter that outputs a displacement amount of a surface position of the target material that covers the holding surface, and the processing unit may acquire the amount of the target material based on the image information and the displacement amount.

In the aforementioned light source apparatus, the holding surface may include a discontinuous part between the first region and the second region, the discontinuous part may not be covered with the target material when the amount of the target material is the first amount, and the discontinuous part may be covered with the target material when the amount of the target material is the second amount.

In the aforementioned light source apparatus, the discontinuous part may be formed in a corner part where a plane of the holding surface that includes the first region and a plane of the holding surface that includes the second region are connected together.

In the aforementioned light source apparatus, the target holding unit may include a crucible that rotates around a rotational axis, and the first region and the second region may be formed on an inner peripheral surface of the crucible.

In the aforementioned light source apparatus, the first region and the second region may each include a part extending along a rotational direction around the rotational axis.

In the aforementioned light source apparatus, the first region and the second region may each include a part extending along a direction of the rotational axis.

In the aforementioned light source apparatus, the target holding unit may include a drum that rotates around a rotational axis, and the first region and the second region may be formed on an outer peripheral surface of the drum.

In the aforementioned light source apparatus, the first region and the second region may each include a part extending along a rotational direction around the rotational axis.

In the aforementioned light source apparatus, the first region and the second region may each include a part extending along a direction of the rotational axis.

A method for controlling a light source apparatus according to the present disclosure includes: an acquisition step of acquiring state information of a holding surface of a target holding unit having the holding surface that holds a target material for generating light; and a processing step of acquiring an amount of the target material based on the state information, in which the holding surface includes a first region and a second region, a depth of the first region from a predetermined surface is greater than that of the second region, the target material is held in the first region when the amount of the target material is a first amount, the target material is held in the first region and the second region when the amount of the target material is a second amount which is greater than the first amount, and the processing step includes acquiring the amount of the target material based on a region in which the target material occupies the holding surface in the state information.

A light source apparatus according to the present disclosure includes: a target holding unit having a holding surface that holds a target material for generating light; an acquisition unit that that includes a camera and acquires image information of the holding surface imaged by the camera; and a processing unit configured to acquire an amount of the target material based on the image information, in which the holding surface includes a first region and a second region, a depth of the first region from a predetermined surface is greater than that of the second region, the target material is held in the first region when the amount of the target material is a first amount, the target material is held in the first region and the second region when the amount of the target material is a second amount which is greater than the first amount, and the processing unit acquires the amount of the target material based on a region in which the target material occupies the holding surface identified in the image information.

A light source apparatus according to the present disclosure includes: a target holding unit having a holding surface that holds a target material for generating light; an acquisition unit that includes a camera and acquires image information of the holding surface imaged by the camera; and a processing unit configured to acquire an amount of the target material based on the image information, in which the holding surface includes a first region and a second region, a depth of the first region from a predetermined surface is greater than that of the second region, the target material is held in the first region when the amount of the target material is a first amount, the target material is held in the first region and the second region when the amount of the target material is a second amount which is greater than the first amount, the holding surface includes a discontinuous part between the first region and the second region, the discontinuous part is not covered with the target material when the amount of the target material is the first amount, the discontinuous part is covered with the target material when the amount of the target material is the second amount, and the processing unit acquires the amount of the target material based on the presence or absence of a specific light in the discontinuous part identified in the image information.

A light source apparatus according to the present disclosure includes: a target holding unit having a holding surface that holds a target material for generating light; an acquisition unit that includes a camera and acquires image information of the holding surface imaged by the camera; and a processing unit configured to acquire an amount of the target material based on the image information, in which the holding surface includes a first region and a second region, a depth of the first region from a predetermined surface is greater than that of the second region, the target material is held in the first region when the amount of the target material is a first amount, the target material is held in the first region and the second region when the amount of the target material is a second amount which is greater than the first amount, the second region has a tip that is projected, and the processing unit acquires the amount of the target material based on the presence or absence of a specific light in the second region identified in the image information.

A method for controlling a light source apparatus according to the present disclosure includes: an acquisition step of acquiring state information of a holding surface of a target holding unit having the holding surface that holds a target material for generating light; and a processing step of acquiring an amount of the target material based on the state information, in which the holding surface includes a first region and a second region, a depth of the first region from a predetermined surface is greater than that of the second region, the target material is held in the first region when the amount of the target material is a first amount, the target material is held in the first region and the second region when the amount of the target material is a second amount which is greater than the first amount, the acquisition step includes acquiring image information of the holding surface imaged by a camera as the state information, and the processing step includes acquiring the amount of the target material based on a region in which the target material occupies the holding surface identified in the image information.

A method for controlling a light source apparatus according to the present disclosure includes: an acquisition step of acquiring state information of a holding surface of a target holding unit having the holding surface that holds a target material for generating light; and a processing step of acquiring an amount of the target material based on the state information, in which the holding surface includes a first region and a second region, a depth of the first region from a predetermined surface is greater than that of the second region, the target material is held in the first region when the amount of the target material is a first amount, the target material is held in the first region and the second region when the amount of the target material is a second amount which is greater than the first amount, the holding surface includes a discontinuous part between the first region and the second region, the discontinuous part is not covered with the target material when the amount of the target material is the first amount, the discontinuous part is covered with the target material when the amount of the target material is the second amount, the acquisition step includes acquiring image information of the holding surface imaged by a camera as the state information, and the processing step includes acquiring the amount of the target material based on the presence or absence of a specific light in the discontinuous part identified in the image information.

A method for controlling a light source apparatus according to the present disclosure includes: an acquisition step of acquiring state information of a holding surface of a target holding unit having the holding surface that holds a target material for generating light; and a processing step of acquiring an amount of the target material based on the state information, in which the holding surface includes a first region and a second region, a depth of the first region from a predetermined surface is greater than that of the second region, the target material is held in the first region when the amount of the target material is a first amount, the target material is held in the first region and the second region when the amount of the target material is a second amount which is greater than the first amount, the second region has a tip that is projected, the acquisition step includes acquiring image information of the holding surface imaged by a camera as the state information, and the processing step acquires the amount of the target material based on the presence or absence of a specific light in the second region identified in the image information.

According to the present disclosure, it is possible to provide a light source apparatus and a method for controlling a light source apparatus capable of acquiring an amount of a target material.

The above and other objects, features and advantages of the present disclosure will become more fully understood from the detailed description given hereinbelow and the accompanying drawings.

### BRIEF DESCRIPTION OF DRAWINGS

FIG. 1 is a sectional view showing an example of a light source apparatus according to a first embodiment, and shows a cross section taken along the line I-I of FIG. 2;

FIG. 2 is a sectional view showing an example of the light source apparatus according to the first embodiment, and shows a cross section taken along the line II-II of FIG. 1;

FIG. 3 is a sectional view showing an example of a groove of a target holding unit in the light source apparatus according to the first embodiment;

FIG. 4 is a sectional view showing an example of another groove of the target holding unit in the light source apparatus according to the first embodiment;

FIG. 5 is a sectional view showing an example of another groove of the target holding unit in the light source apparatus according to the first embodiment;

FIG. 6 is a sectional view showing an example of another groove of the target holding unit in the light source apparatus according to the first embodiment;

FIG. 7 is a diagram showing an example of another groove of the target holding unit in the light source apparatus according to the first embodiment;

FIG. 8 is a sectional view showing an example of another groove of the target holding unit in the light source apparatus according to the first embodiment;

FIG. 9 is a configuration diagram showing an example of an acquisition unit in the light source apparatus according to the first embodiment;

FIG. 10 is a sectional view showing an example of a light source apparatus according to a second embodiment, and shows a cross section taken along the line X-X of FIG. 11;

FIG. 11 is a sectional view showing an example of the light source apparatus according to the second embodiment, and shows a cross section taken along the line XI-XI of FIG. 10;

FIG. 12 is a sectional view showing an example of a groove of a target holding unit in the light source apparatus according to the second embodiment;

FIG. 13 is a side view showing an example of another groove of the target holding unit in the light source apparatus according to the second embodiment;

FIG. 14 is a perspective view showing an example of another groove of the target holding unit in the light source apparatus according to the second embodiment; and

FIG. 15 is a flowchart showing an example of a method for controlling the light source apparatus according to the first and second embodiments.

### DESCRIPTION OF EMBODIMENTS

A specific configuration of the present embodiment is described below with reference to the drawings. The following description indicates preferred embodiments of the present disclosure. The scope of the present disclosure is not limited to the following embodiments. In the following description, what is assigned the same symbol indicates similar content.

### First Embodiment

A light source apparatus according to a first embodiment is described. The light source apparatus of the present embodiment generates light, such as illumination light and exposure light, used for an optical apparatus, such as an inspection apparatus and a lithography apparatus. The light source apparatus may be provided integrally with the optical apparatus, or be disposed, as an apparatus separated from the optical apparatus, adjacent to the optical apparatus. In the case where the optical apparatus is an inspection apparatus, the light source apparatus generates illumination light with which an inspection target in the inspection apparatus is illuminated. In the case where the optical apparatus is the lithography apparatus, the light source apparatus generates exposure light with which an exposure target in the lithography apparatus is exposed.

The light source apparatus irradiates a target material held in a target holding unit with excitation light, thereby generating light, such as illumination light and exposure light. In the following first embodiment, as an example of the light source apparatus, an example in which a liquid target material is held in a target holding unit including a container such as a crucible is described. In a second embodiment, an example in which a solid target material is held in a target holding unit, such as a cylindrical drum, is described. Note that the light source apparatus is not limited to the one that uses a liquid target material held in a container, such as a crucible, and the one that uses a solid target material held in a cylindrical drum or the like, and may be the one that uses a tape-shaped target material or a target material dropped or ejected in a droplet shape.

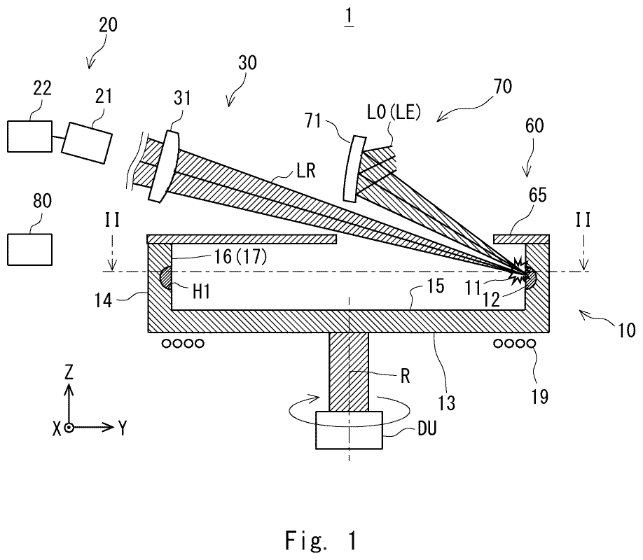

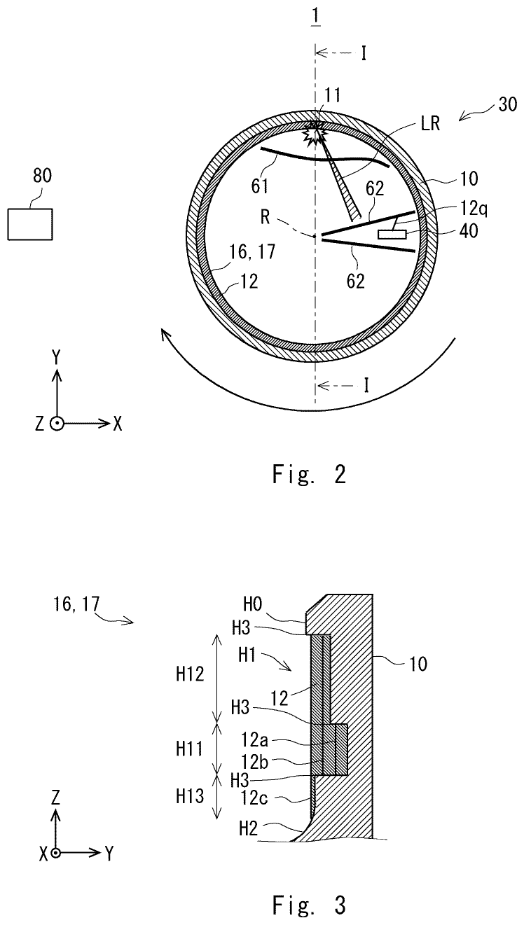

FIG. 1 is a sectional view showing an example of a light source apparatus 1 according to the first embodiment, and shows a cross section taken along the line I-I of FIG. 2. FIG. 2 is a sectional view showing an example of the light source apparatus 1 according to the first embodiment, and shows a cross section taken along the line II-II of FIG. 1. In FIGS. 1 and 2, some of members are sometimes omitted in order to prevent the drawings from being complicated. Further, some of the reference signs may be omitted. The same holds true for the subsequent drawings.

As shown in FIGS. 1 and 2, the light source apparatus 1 includes a target holding unit 10, an acquisition unit 20, and a processing unit 22. Note that the light source apparatus 1 may further include, besides the target holding unit 10, the acquisition unit 20, and the processing unit 22, a drive unit DU, a formation unit 30, a supply unit 40, a cover part 60, an output optical system 70, and a control unit 80.

Here, for the sake of convenience in describing the light source apparatus 1, an XYZ orthogonal coordinate system is introduced. For example, a rotational axis R of the target holding unit 10 is assumed as the Z axis direction. Note that the introduced XYZ orthogonal coordinate system is for the sake of convenience in description, and does not limit the orientation of each member.

The target holding unit 10 holds the target material 12 for generating light. The target holding unit 10 may include, for example, a container such as a crucible. The target holding unit 10 allows metal to melt inside. The target holding unit 10 holds a liquid target material 12 for forming plasma 11 due to irradiation with excitation light LR. The excitation light LR is, for example, laser light including Infrared (IR) light.

Note that as described later, the target holding unit 10 is not limited to what includes a container, such as a crucible. For example, the target holding unit 10 may be a cylindrical (cylinder-shaped) drum. In this case, the target holding unit 10 holds the target material 12 by fixing a substance serving as this target material 12, such as frozen xenon (Xe), on the surface of the drum in a solid state, for example.

The target material 12 is not limited to a substance in a liquid state held in the target holding unit 10, and may include a substance in a solid state, such as a tape-shaped substance and a solid metal, as long as it is a substance that forms the plasma 11 by irradiation with excitation light LR. The substance in a liquid state is, for example, molten metal such as molten tin (Sn), lithium (Li), or the like, but is not limited to tin, lithium or the like as long as it generates the plasma 11 by irradiation with excitation light LR.

The target holding unit 10 has the rotational axis R, and rotates around the rotational axis R centered at the rotational axis R. For example, the target holding unit 10 includes a crucible or the like that rotates around the rotational axis R. The rotational axis R may be substantially orthogonal to a contact surface. This applies a centrifugal force uniformly to the target material 12 held in the target holding unit 10. Accordingly, the thickness of the target material 12 can become uniform, which can stabilize light L0 extracted from the light source apparatus 1.

The target holding unit 10 has, for example, a cylindrical shape with one opening being closed. Note that the target holding unit 10 may have a shape other than the cylindrical shape, such as a mortar shape or a barrel shape, as long as it can hold the target material 12. The closed portion of the target holding unit 10 is called a bottom part 13. The cylindrical portion of the target holding unit 10 is called a cylindrical part 14. An inner surface of the bottom part 13 is called a bottom surface 15. The inner surface of the cylindrical part 14 is called an inner peripheral surface 16.

The target holding unit 10 has a holding surface 17 that holds the target material 12. For example, the target holding unit 10 has an inner peripheral surface 16 as the holding surface 17. In this case, the target holding unit 10 holds the target material 12 on the inner peripheral surface 16 by the centrifugal force. Note that the target holding unit 10 may adopt a surface, such as the bottom surface 15, other than the inner peripheral surface 16, as the holding surface 17, as long as it can hold the target material 12. That is, the holding surface 17 may have, besides the inner peripheral surface 16, a surface other than the inner peripheral surface 16, or may not have the inner peripheral surface 16 and have a surface other than the inner peripheral surface 16.

The inner peripheral surface 16 formed to surround the rotational axis R may have a concave part formed along the inner peripheral surface 16. The concave part includes, for example, a groove H1. In the following description, it is assumed that the concave part is the groove H1. The holding surface 17 may have a concave groove H1. For example, the groove H1 is formed along an intersection of the inner peripheral surface 16 with the surface orthogonal to the rotational axis R. The groove H1 is formed concave in the inner peripheral surface 16 in a direction away from the rotational axis R. In the case where the inner peripheral surface 16 has the groove H1, the target material 12 may be held in the groove H1. By holding the target material 12 in the groove H1, the movement of the target material 12 in the Z axis direction can be limited, which can prevent the liquid surface of the target material 12 from being disturbed. Furthermore, the amount of the target material 12 can be limited within the groove H1. Accordingly, the required amount of the target material 12 can be reduced. Note that the part of the target material 12 may be positioned outside of the groove H1.

FIG. 3 is a sectional view showing an example of the groove H1 of the target holding unit 10 in the light source apparatus 1 according to the first embodiment. As shown in FIG. 3, the inner peripheral surface 16 as the holding surface 17 may include, besides the groove H1, a cylindrical part H0 having a cylindrical shape that has a constant distance from the rotational axis R. The inner peripheral surface 16 may further include an inclined surface H2 that varies in distance from the rotational axis R. For example, the inner peripheral surface 16 may include the inclined surface H2 provided with a corner R at a portion connected to the bottom surface 15. Therefore, the holding surface 17 may include the cylindrical surface H0, the groove H1, and the inclined surface H2. For example, the groove H1 is formed between the cylindrical surface H0 and the inclined surface H2 in the Z axis direction. Note that the holding surface 17 is not limited to the one that includes the cylindrical surface H0, the groove H1, the inclined surface H2, and the like, and may not include some of the cylindrical surface H0, the groove H1, and the inclined surface H2, as long as the holding surface 17 can hold the target material 12.

The groove H1 may include a first region H11, a second region H12, and a third region H13. Accordingly, the holding surface 17 may include the first region H11, the second region H12, and the third region H13. Note that the holding surface 17 may not necessarily include all the first region H11, the second region H12, and the third region H13 as long as it includes at least one of the first region H11, the second region H12, and the third region H13.

The first region H11, the second region H12, and the third region H13 are formed on the inner peripheral surface 16 of the crucible. Specifically, the first region H11, the second region H12, and the third region H13 are formed along an intersection between the inner peripheral surface 16 and a surface orthogonal to the rotational axis R. Accordingly, the first region H11, the second region H12, and the third region H13 are formed in an annular shape on the inner peripheral surface 16. In other words, the first region H11, the second region H12, and the third region H13 each have a part extending along the rotational direction around the rotational axis R.

The first region H11, the second region H12, and the third region H13 may be continuously formed in an annular shape in the rotational direction. Further, the first region H11, the second region H12, and the third region H13 may each include a plurality of parts formed to be aligned in the rotational direction. As will be described later, each region, such as, for example, the first region H11, the second region H12, and so on, may each have a part extending in the direction of the rotational axis R.

The first region H11 is disposed on the +Z axis direction side with respect to the third region H13. The first region H11 is disposed on the −Z axis direction side with respect to the second region H12. The second region H12 is disposed on the +Z axis direction side with respect to the first region H11. The second region H12 is disposed on the −Z axis direction side with respect to the cylindrical part H0. The third region H13 is disposed on the −Z axis direction side with respect to the first region H11. The third region H13 is disposed on the +Z axis direction side with respect to the inclined part H2.

The cross section of the first region H11 has a rectangular shape that is opened on the side of the rotational axis R. The cross section of the second region H12 is formed in a step shape between the cylindrical part H0 and the first region H11 in the Z axis direction. The cross section of the third region H13 is formed in a step shape between the inclined surface H2 and the first region H11 in the Z axis direction.

Each part of the first region H11, the second region H12, and the third region H13 in the groove H1 may have depths different from one another. That is, each part of the first region H11, the second region H12, and the third region H13 may be disposed at different positions with respect to a predetermined surface of the holding surface 17 in which the groove H1 is formed in a direction away from the rotational axis R. For example, when a predetermined surface of the holding surface 17 in which the groove H1 is formed is the cylindrical surface H0, each part of the first region H11, the second region H12, and the third region H13 may be disposed at different positions with respect to the cylindrical surface H0 in a direction away from the rotational axis R.

As described above, when the distance from a predetermined surface of the holding surface 17 to the rotational axis R is defined to be a reference distance, an absolute value of a difference between the reference distance and the distance from each part of the first region H11, the second region H12, and the third region H13 to the rotational axis R is called a depth. Further, the depth of each part of the first region H11, the second region H12, and the third region H13 is also a distance from the predetermined surface to each part in the direction orthogonal to the direction of the surface of the target material 12. The predetermined surface is located on the side of the surface of the target material 12. The distance from the rotational axis to the predetermined surface of the holding surface 17 may be shorter than the distance from the rotation axis to the first region H11, the second region H12, and the third region H13. In this embodiment, the length obtained by subtracting the reference distance from the distance between each part of the first region H11, the second region H12, and the third region H13, and the rotational axis R is a depth.

While the reference distance is defined, for example, as the distance from the cylindrical surface H0 to the rotational axis R, this is merely an example. The reference distance may be the distance from the shallowest third region H13 to the rotational axis R. A surface serving as a reference for introducing the reference distance is called a predetermined surface. Then, the depth of the first region H11 from the predetermined surface is greater than the depth of the second region H12 from the predetermined surface. The depth of the second region H12 from the predetermined surface is greater than the depth of the third region H13 from the predetermined surface. In this embodiment, the depth can be simply defined as a distance from the rotational axis R.

The depth of the first region H11, the depth of the second region H12, and the depth of the third region H13 may each have a predetermined range. For example, the depth of the third region H13 may be greater than a fourth depth (the depth of the cylindrical surface H0) (deeper than the fourth depth) and equal to or smaller than a third depth (the same as the third depth or smaller than the third depth). The depth of the second region H12 may be greater than the third depth (greater than the third depth) and equal to or smaller than a second depth (the same as the second depth or smaller than the second depth). The depth of the first region H11 may be greater than the second depth (deeper than the second depth) and equal to or smaller than a first depth (the same as the first depth or smaller than the first depth). Here, the first depth>the second depth>the third depth>the fourth depth is satisfied.

The holding surface 17 may include a discontinuous part H3 defined later between the first region H11 and the second region H12. The holding surface 17 may include the discontinuous part H3 between the first region H11 and the third region H12.

As shown in FIG. 3, the cross section of the second region H12 is formed in a step shape between the cylindrical part H0 and the first region H11 in the Z axis direction. In this manner, at a boundary between the first region H11 and the second region H12, the depth of the first region H11 and the depth of the second region H12 may be changed discontinuously and a part shallower than the first region H11 may be formed. Like in this example, the part of the boundary where the depth changes discontinuously may be referred to as a discontinuous part H3.

The surface of the target material 12 includes a flat part. Therefore, the surface of the target material 12 reflects emitting light of the plasma 11 or light such as a predetermined illumination light in a fixed direction. On the other hand, the discontinuous part H3 reflects or scatters emitting light of the plasma 11 or light such as a predetermined illumination light in an aspect different from that on the surface of the target material 12. Accordingly, the discontinuous part H3 is provided between the first region H11 and another region, whereby it is possible to easily determine, from the presence or absence of the specific light (e.g., reflected light, scattered light or the like), whether the target material 12 is held only in the first region H11 or is held in the second region H12 as well as the first region H11. This is because, when the second region H12 as well as the first region H11 holds the target material 12, the discontinuous part H3 between the first region H11 and the second region H12 is covered with the target material 12 and the occurrence of the reflected light or the scattered light from the discontinuous part H3 is suppressed.

The position where the discontinuous part H3 is formed is not limited to a part between the first region H11 and another region, and the discontinuous part H3 may be formed between the second region H12 and another region or between the third region H13 and another region.

The target material 12 is held in the first region H11 when the amount of the target material 12 is a first amount 12a. More specifically, when the amount of the target material 12 is the first amount 12a, the target material 12 is held in the first region H11 and is not held in the second region H12. When the amount of the target material 12 is the first amount 12a, the target material 12 may be held in the first region H11 and not held in the second region H12 and the third region H13. The first amount 12a may be a constant value or may have a predetermined range. The amount held in the first region H11 may be the first amount 12a. When the amount of the target material 12 is a second amount 12b which is greater than the first amount 12a, the target material 12 is held in the first region H11 and the second region H12. More specifically, when the amount of the target material 12 is the second amount 12b, the target material 12 is held in the first region H11 and the second region H12 and is not held in the third region H13. The second amount 12b may be a constant value or may have a predetermined range. The amount held in the second region H12 may be the second amount 12b. When the amount of the target material 12 is a third amount 12c which is greater than the second amount 12b, the target material 12 is held in the first region H11, the second region H12, and the third region H13. The third amount 12c may be a constant value or may have a predetermined range. The amount held in the third region H13 may be the third amount 12c. For clarity, in the description of this embodiment, the phrase “the target material 12 is held in N-th region” may be understood to mean that the target material 12 comes into contact with the N-th region when the target holding unit 10 is rotating at a sufficient speed such that the target material 12 is subjected to centrifugal force and remains against the holding surface 17. Similarly, the phrase “the target material 12 covers or occupies a certain part or region” may also be understood in the same manner. In situations where the light source apparatus is operated to irradiate the target material 12 with excitation light and extract the generated light, it may be considered that the target holding unit 10 is rotating at a sufficient speed.

When the holding surface 17 has a discontinuous part H3 between the first region H11 and the second region H12, the discontinuous part H3 is not covered with the target material 12 when the amount of the target material 12 is the first amount 12a, and is covered with the target material 12 when the amount of the target material 12 is the second amount 12b. Likewise, when, for example, the holding surface 17 has a discontinuous part H3 between the second region H12 and the third region H13, the discontinuous part H3 is not covered with the target material 12 when the amount of the target material 12 is the second amount 12b, and is covered with the target material 12 when the amount of the target material 12 is the third amount 12c.

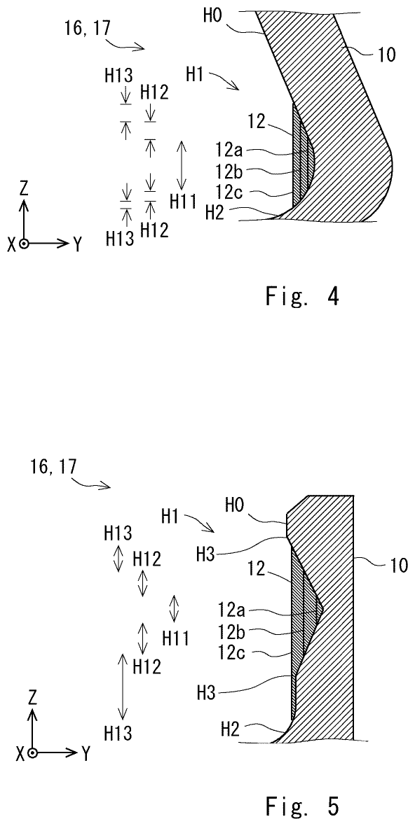

FIGS. 4-6 are sectional views each showing an example of another groove H1 of the target holding unit 10 in the light source apparatus 1 according to the first embodiment. As shown in FIG. 4, the cross section of the groove H1 may have a form in which an arc part and a linear part are connected together. The first region H11 is disposed in the deepest part of the groove H1, that is, a part of the groove H1 which is the farthest from the rotational axis R. The second region H12 and the third region H13 are disposed in sequence from the first region H11 in the +Z axis direction. The second region H12 and the third region H13 are also disposed in sequence from the first region H11 in the −Z axis direction. The first region H11 is disposed in such a way that it is held between the two second regions H12. The first region H11 and the second regions H12 are disposed in such a way that they are held between the two third regions H13.

With the aforementioned configuration as well, the target material 12 is held in the first region H11 when the amount of the target material 12 is the first amount 12a. The target material 12 is held in the first region H11 and the second region H12 when the amount of the target material 12 is the second amount 12b which is greater than the first amount 12a. The target material 12 is held in the first region H11, the second region H12, and the third region H13 when the amount of the target material 12 is the third amount 12c which is greater than the second amount 12b.

As shown in FIG. 5, the cross section of the groove H1 may have a transverse V shape. The V-shaped opening faces the rotational axis R. The first region H11 is disposed in the deepest part of the groove H1, that is, a part of the groove H1 which is the farthest from the rotational axis R. The second region H12 and the third region H13 are disposed in sequence from the first region H11 in the +Z axis direction. The second region H12 and the third region H13 are also disposed in sequence from the first region H11 in the −Z axis direction. The first region H11 is disposed in such a way that it is held between the two second regions H12. The first region H11 and the second regions H12 are disposed in such a way that they are held between the two third regions H13. The correspondence between the amount of the target material 12 and the region in which the target material 12 is held is similar to that shown in FIG. 4.

For example, an angle between a surface including the first region H11 or the like and a predetermined surface (e.g., this surface may be the surface of the target material 12) may be different from an angle between a surface including the second region H12 or the like and the predetermined surface. In this manner, the angles of the surfaces including two regions (which are adjacent and distinct from each other) relative to the predetermined surface may be different from each other at the boundary between the two regions. That is, the angle of the surface including each region at the boundary of two regions may be changed discontinuously. In this manner, a part where the angle to the predetermined surface discontinuously changes may be also called a discontinuous part H3. The discontinuous part H3 may be formed in a corner part where a plane of the holding surface 17 that includes the first region H11 and a plane of the holding surface 17 that includes the second region H12 are connected together. The discontinuous part H3 may be formed in a corner part where the plane of the holding surface 17 that includes the second region H12 and the plane of the holding surface 17 that includes the third region H13 are connected together.

Based on the above-described discussion, the discontinuous part H3 may indicate at least one of the part of the border where the depth changes discontinuously, such as a step shape, and the part of the border where the angle changes discontinuously.

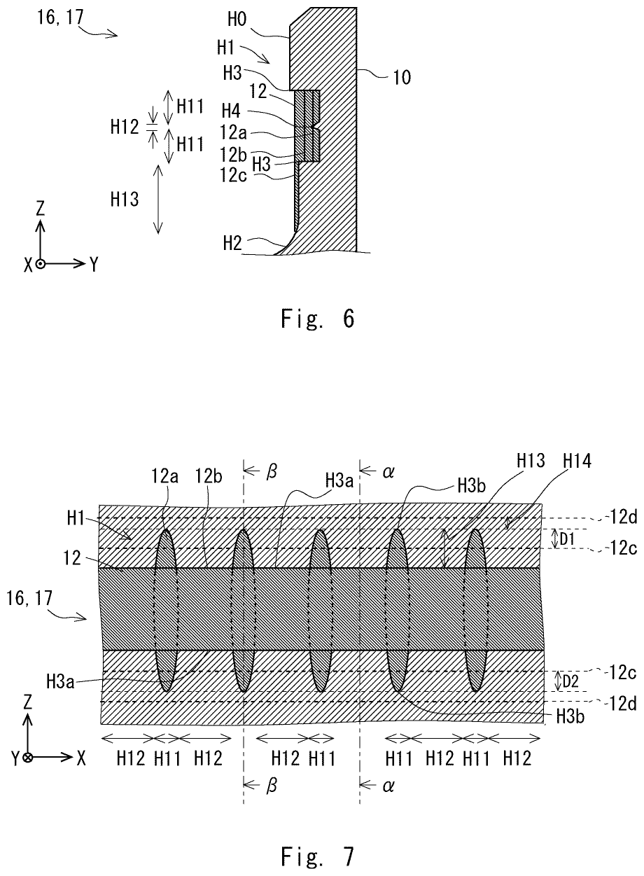

As shown in FIG. 6, two first regions H11 are disposed on the +Z axis direction side with respect to the third region H13. The two first regions H11 are vertically aligned in the Z axis direction. The second region H12 is disposed in such a way that it is held between the two first regions H11. The second region H12 is formed in a shape in which the tip thereof is projected. Accordingly, when a projecting part H4 as the second region H12 is projected on the surface of the target material 12, it can be said that the target material 12 is held in the first region H11 and is not held in the second region H12. Therefore, in this case, the amount of the target material 12 is the first amount 12a. Until the time when the projecting part H4 is covered with the target material 12 and the target material 12 occupies the third region H13, the target material 12 is held in the first region H11 and the second region H12 and is not held in the third region H13. Therefore, in this case, the amount of the target material 12 is the second amount 12b.

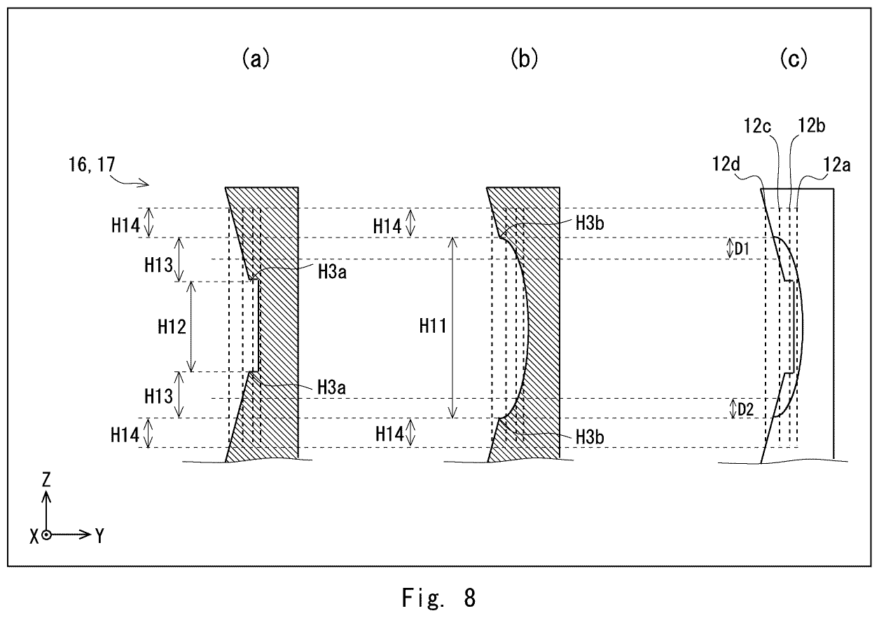

FIG. 7 is a diagram showing an example of another groove H1 of the target holding unit 10 in the light source apparatus 1 according to the first embodiment. FIG. 8 is a sectional view showing an example of another groove H1 of the target holding unit 10 in the light source apparatus 1 according to the first embodiment, in which (a) shows the cross section of α-α of FIG. 7, (b) shows the cross section of β-β of FIG. 7, and (c) shows (a) and (b) in an overlapping manner. As shown in FIGS. 7 and 8, the first region H11 and the second region H12 may each have a part extending in the direction of the rotational axis R. The holding surface 17 has a plurality of first regions H11. The plurality of first regions H11 are formed so as to align in the rotational direction around the rotational axis R along the holding surface 17. The plurality of first regions H11 extend in a direction of the rotational axis R. Specifically, each of the first regions H11 includes a groove extending in the direction of the rotational axis R. The second region H12 is formed between first regions H11 adjacent to each other. The plurality of second regions H12 extend in a direction of the rotational axis R. The position of the end part on the +Z direction side of the first region H11 extending in the direction of the rotational axis R is on the +Z axis side with respect to the position of the end part on the +Z axis direction side of the second region H12. The position of the end part on the −Z direction side of the first region H11 extending in the direction of the rotational axis R is on the −Z axis side with respect to the position of the end part on the −Z axis direction side of the second region H12.

When the amount of the target material 12 is the first amount 12a, the target material 12 is held in the groove in the first region H11. When the amount of the target material 12 is the second amount 12b, the target material 12 is held in the first region H11 and the second region H12.

The holding surface 17 may further include a third region H13 and a fourth region H14. The third region H13, which is a region between first regions H11 adjacent to each other, includes regions other than the second region H12. Therefore, the third region H13 includes a plurality of regions on the +Z axis direction side with respect to the second region H12 and a plurality of regions on the −Z axis direction side with respect to the second region H12. The fourth region H14 includes a ring-shaped region on the +Z axis direction side with respect to a region including the first region H11, the second region H12, and the third region H13 and a ring-shaped region on the −Z axis direction side with respect to a region including the first region H11, the second region H12, and the third region H13. When the amount of the target material 12 is the third amount 12c, the target material 12 is held in the first region H11, the second region H12, and the third region H13. When the amount of the target material 12 is a fourth amount 12d, the target material 12 is held in the first region H11, the second region H12, the third region H13, and the fourth region H14. Regarding the amount of the target material 12, the first amount 12a<the second amount 12b<the third amount 12c<the fourth amount 12d is satisfied. A discontinuous part H3b is formed between the first region H11, and the third region H13 and the fourth region H14. A discontinuous part H3a is formed between the second region H12 and the third region H13.

When the amount of the target material changes from the fourth amount 12d to the third amount 12c, which is smaller than the fourth amount 12d, a specific light occurs from the discontinuous part H3b in a circumferential region having the cross section of FIG. 8(b). Therefore, the processing unit 22 can acquire the amount of the target material 12 based on the presence or absence of a specific light from the discontinuous part H3b in an image captured by the acquisition unit 20. Like in this example, the discontinuous part H3b may be formed in only a part of the circumferential region of the entire circumference.

Further, when the amount of the target material 12 has been changed from the fourth amount 12d to the third amount 12c, which is smaller than the fourth amount 12d, the width of the region occupied by the target material 12 in the circumferential region having the cross section of FIG. 8(b) is wider than that in the circumferential region having the cross section of FIG. 8(a) by the amount corresponding to the length of the length D1+length D2 shown in FIG. 8(c). Then, when the captured image in which the circumferential region having the cross section of FIG. 8(b) and the circumferential region having the cross section of FIG. 8(a) are exposed has been acquired in the acquisition unit 20, parameters such as the luminance and the contrast of the captured image acquired from the acquisition unit 20 when the amount of the target material 12 is the third amount 12c is different from those of the captured image acquired from the acquisition unit 20 when the amount of the target material 12 is the fourth amount 12d. This is because, when the amount of the target material 12 is the fourth amount 12d, the target material 12 whose width corresponds to the length D1+the length D2 (depending on the angle of view, a part thereof) captured for the entire circumference, whereas, when the amount of the target material 12 is the third amount 12c, the target material 12 is not imaged in a part of the circumferential region, that is, not imaged in a circumferential region having the cross-sectional structure of (a). Therefore, the processing unit 22 may acquire the amount of the target material 12 from a change in the luminance, the contrast, or the like of the captured image in the acquisition unit 20. In other words, in a part of the region in the circumferential direction, the first region H11 and the second region H12 are formed as a part extending in the direction of the rotational axis R, and the position of the end part on +Z direction side (and/or −Z direction side) of the first region H11 at this time is on +Z axis side (and/or −Z direction side) with respect to the position of the end part on the +Z axis direction side (and/or −Z direction side) of the second region H12, whereby the processing unit 22 can acquire the amount of the target material 12 from a change in the luminance, the contrast, or the like of the captured image in the acquisition unit 20.

Further, when the amount of the target material 12 is changed from the third amount 12c to the second amount 12b, which is smaller than the third amount 12c, a specific light occurs from the discontinuous part H3a in a circumferential region having the cross section of FIG. 8(a). Therefore, the processing unit 22 can acquire the amount of the target material 12 based on the presence or absence of a specific light from the discontinuous part H3a in the image captured by the acquisition unit 20. Like in this example, the discontinuous part H3a may be formed in only a part of the circumferential region of the entire circumference.

Note that the first region H11 and the second region H12 in FIG. 7 may have opposite configurations. That is, the part of the groove extending along the direction of the rotational axis R may be shallower than the part formed between grooves adjacent to each other. Accordingly, the second region H12 includes the part of the groove extending along the direction of the rotational axis R and the first region H11 includes the part formed between the grooves adjacent to each other. Note that the first regions H11 may be integrated so as to connect together the plurality of parts formed between grooves adjacent to each other and formed in a belt shape along the inner peripheral surface 16. In this manner, the holding surface 17 may include the first region H11 extending along the rotational direction around the rotational axis R and the second region H12 extending along the direction of the rotational axis R.

As shown in FIG. 1, a heater 19 is provided in the target holding unit 10. Heating by the heater 19 can form a liquid target material 12 in the target holding unit 10.

The drive unit DU is connected to the target holding unit 10 via a power transmission mechanism such as a shaft. The drive unit DU drives the target holding unit 10 by transmitting the power to the target holding unit 10. The drive unit DU moves the holding surface 17 by driving the target holding unit 10. For example, the drive unit DU transports the target material 12 to the target holding unit 10 by rotating the target holding unit 10 around the rotational axis R.

The acquisition unit 20 acquires information on the holding surface 17 of the target holding unit 10. The information on the holding surface 17 is called state information. The acquisition unit 20 may include a camera 21. The acquisition unit 20 may include a camera 21 that captures images by visible light or may include a camera 21 that captures images by light other than the visible light. The acquisition unit 20 may include a camera 21 that captures a still image or may include a camera 21 that captures a moving image.

The acquisition unit 20 acquires image information of the holding surface 17 imaged by the camera 21 as state information of the holding surface 17 of the target holding unit 10. Specifically, the camera 21 images the groove H1, whereby the acquisition unit 20 acquires image information of the groove H1. For example, the camera 21 images the target material 12 held in the first region H11. Accordingly, the acquisition unit 20 may acquire first image information in which it is identified that the target material 12 is held in the first region H11 and is not held in the second region H12. Further, the camera 21 images the target material 12 held in the first region H11 and the second region H12. Accordingly, the acquisition unit 20 acquires second image information in which it may be identified that the target material 12 is held in the first region H11 and the second region H12. Likewise, the camera 21 images the target material 12 held in the first region H11, the second region H12, and the third region H13. Accordingly, the acquisition unit 20 acquires third image information in which it is identified that the target material 12 is held in the first region H11, the second region H12, and the third region H13. The acquisition unit 20 outputs the acquired state information to the processing unit 22.

The processing unit 22 acquires the amount of the target material 12 based on the region in which the target material 12 occupies the holding surface 17 in the acquired state information (that is, identified based on the state information). The processing unit 22 may acquire the amount of the target material 12 based on at least one of a width and an area of a region in which the target material 12 occupies the holding surface 17 in the image information. The width and the area of the region in which the target material 12 occupies the holding surface 17 may be identified based on the region in a part of the captured image that is identified as the target material 12. The processing unit 22 may acquire the amount of the target material 12 as entire amount of the target material 12 held by the target holding unit 10, like the amount or the like of the target material 12 included in the container that has the holding surface 17, or as the amount of the target material 12 in a part of the region of the holding surface 17 (e.g., region in which the state information has been acquired).

The processing unit 22 may acquire the amount of the target material 12 based on the presence or absence of a specific light from the discontinuous part H3 or the presence or absence of a specific light from the second region H12 (e.g., projecting part H4) in the acquired state information (that is, identified based on the state information). The processing which is based on the presence or absence of a specific light from the discontinuous part H3 and the presence or absence of a specific light from the second region H12 (e.g., projecting part H4) is one example of processing based on a region in which the target material 12 occupies the holding surface 17. Acquiring the amount of the target material 12 may include estimating and predicting the amount of the target material 12, determining and estimating that the amount of the target material 12 has decreased or increased from a predetermined level, and so on. The processing unit 22 may acquire information related to the amount of the target material 12 based on the region in which the target material 12 occupies the holding surface 17 in the acquired state information (that is, identified based on the state information). The information related to the amount of the target material 12 may include, for example, the amount of the target material 12, and that the amount of the target material 12 has increased or decreased from a predetermined level, and the acquiring processing may include estimating and predicting processing.

Further, the processing unit 22 may control the amount of supply of the target material 12 in the supply unit 40 based on the region in which the target material 12 occupies the holding surface 17 in the acquired state information (that is, identified based on the state information). For example, the processing unit 22 performs control so as to increase the amount of supply from the supply unit 40 in order to compensate for a decrease in the amount of the target material 12, or performs control so as to decrease the amount of supply from the supply unit 40 in order to deal with an increase in the amount of the target material 12. Further, the processing unit 22 may control the formation unit 30; for example, the processing unit 22 may control an irradiation frequency of the excitation light LR, the posture of an optical element, or the like based on the region in which the target material 12 occupies the holding surface 17 in the acquired state information (that is, identified based on the state information). In this manner, the processing unit 22 may execute various kinds of control based on information related to the amount of the target material 12 that has been acquired and control of the state of the light source apparatus. Further, the processing unit 22 may acquire control information which is based on the amount of the target material 12 based on the region in which the target material 12 occupies the holding surface 17 in the acquired state information (that is, identified based on the state information). The processing unit 22 may control, based on the control information which is based on the amount of the target material 12, the state of the light source apparatus such as the supply unit 40, the formation unit 30 or the like.

For example, the processing unit 22 determines that the amount of the target material 12 is the first amount 12a when the camera 21 has acquired the first image information. Accordingly, the processing unit 22 acquires the first amount 12a as the amount of the target material 12. The processing unit 22 determines that the amount of the target material 12 is the second amount 12b when the camera 21 has acquired the second image information. Accordingly, the processing unit 22 acquires the second amount 12b as the amount of the target material 12. The processing unit 22 determines that the amount of the target material 12 is the third amount 12c when the camera 21 has acquired the third image information. Accordingly, the processing unit 22 acquires the third amount 12c as the amount of the target material 12.

The processing unit 22 may predict the amount of the target material 12 based on the region in which the target material 12 occupies the holding surface 17 in the acquired state information (that is, identified based on the state information). That is, the processing unit 22 may acquire a predicted amount of the target material 12. For example, the processing unit 22 acquires supply information regarding supply of the target material 12 by the supply unit 40 directly from the supply unit 40 or indirectly via the control unit 80 or the like. The processing unit 22 may predict the amount of the target material 12 based on the supply information and the state information.

The processing unit 22 may acquire state information of the holding surface 17 from detection means such as a sensor other than the camera 21. For example, the processing unit 22 may acquire state information of the holding surface 17 from the position of the target material 12 detected by the position sensor. The position sensor detects the position of the end part of the target material 12. Accordingly, the position sensor may detect at least one of the width and the area of the region in which the target material 12 occupies the holding surface 17. The position sensor may include, for example, a displacement meter, a high-speed camera, a low-speed camera, a quadrant PD (Photo Diode), or a TDI (Time Delay Integration) camera. The position sensor may be any of what one-dimensionally measures the surface position, what two-dimensionally measures it, and what three-dimensionally measures it, or a combination of some of them. In this manner, the acquisition unit 20 may include a displacement meter that outputs a displacement amount of the surface position of the target material 12 that covers the holding surface 17. The processing unit 22 may acquire the amount of the target material 12 based on the image information and the displacement amount.

Further, the processing unit 22 may use together the camera 21, the position sensor, and so on. The processing unit 22 may use one of the camera 21, the position sensor and the like for auxiliary application of the other one of them. Specifically, state information acquired by one of the camera 21, the position sensor and the like may be corrected by the other one of them. For example, the processing unit 22 may acquire or predict the amount of the target material 12 by combining the position sensor or the like with the image information acquired by the camera 21.

Further, the acquisition unit 20 may include a photodetector that detects a specific light from the discontinuous part H3 and may acquire, as the state information, information regarding the presence or absence of the specific light from the discontinuous part H3 or the intensity thereof.

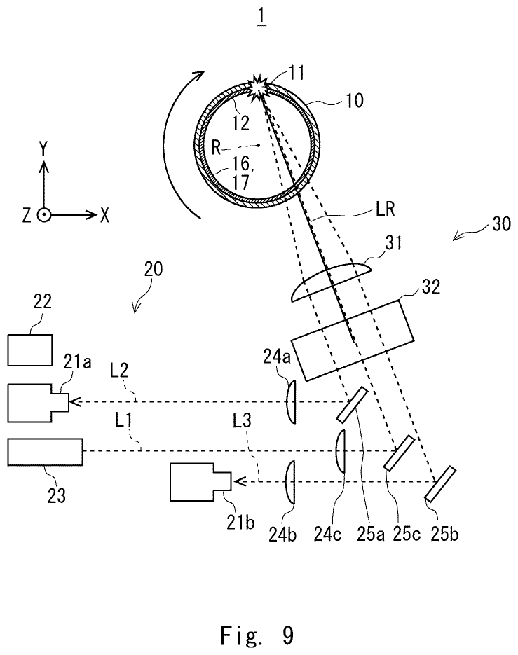

FIG. 9 is a configuration diagram showing an example of the acquisition unit 20 in the light source apparatus 1 according to the first embodiment. As shown in FIG. 9, the acquisition unit 20 may further include a plurality of cameras 21a and 21b, an illumination unit 23, lenses 24a-24c, and mirrors 25a-25c. Note that the acquisition unit 20 may further include optical members other than those stated above, or some of these optical members may be omitted.

The illumination unit 23 generates and emits illumination light L1. The illumination light L1 emitted from the illumination unit 23 illuminates, for example, the target holding unit 10 via the lens 24c, the mirror 25c, the mirror 32, and the condenser lens 31. The camera 21a images light L2 from a bright spot of the plasma 11 via the condenser lens 31, the mirror 32, the mirror 25a, and the lens 24a. The camera 21b images light L3 from the holding surface 17 via the condenser lens 31, the mirror 32, the mirror 25b, and the lens 24b. Accordingly, the camera 21b acquires image information of the holding surface 17.

The cameras 21, 21a, and 21b in the acquisition unit 20 may image the holding surface 17 of the target holding unit 10 via the condenser lens 31 that focuses excitation light LR. Accordingly, the target material 12 at the position irradiated with the excitation light LR can be imaged, whereby the accuracy of the amount of the target material 12 can be improved. Further, a hole for the optical path of the excitation light LR formed in a debris cover 65 and a hole for enabling the camera 21 to capture images can be shared, whereby the number of holes formed in the debris cover 65 can be reduced. Therefore, the adverse effect of debris in the light source apparatus 1 can be reduced.

The formation unit 30 may include optical members. The optical members include the condenser lens 31 that focuses the excitation light LR on the target material 12 and the mirror 32 that reflects the excitation light LR. The formation unit 30 excites the target material 12 by focusing the laser light on the target material 12 as the excitation light LR.

As shown in FIGS. 1 and 2, the formation unit 30 forms the plasma 11 from the target material 12. When the plasma 11 is formed, EUV light LE is generated from the plasma 11. For example, the EUV light LE is used as light L0 for illumination, exposure, and the like, in an optical apparatus such as an inspection apparatus, a lithography apparatus or the like.

Note that the optical member in the formation unit 30 is not limited to a condenser lens 31 and a mirror 32, and may include a laser apparatus that generates the excitation light LR, as long as it irradiates the target material 12 with the excitation light LR. That is, the light source apparatus 1 may include a laser apparatus that generates the excitation light LR. On the other hand, the light source apparatus 1 may introduce, into the light source apparatus 1, excitation light LR from a laser apparatus installed separately from the light source apparatus 1 outside of the light source apparatus 1. The excitation light LR may irradiate the target material 12 by the laser apparatus under control by the control unit 80.

The supply unit 40 supplies the target material 12 to the target holding unit 10. The supply unit 40 may supply a solid target material 12 to the target holding unit 10. The solid target material 12 may have a linear shape. The linear target material 12 may be held in a state of being wound around a bobbin or the like. The supply unit 40 supplies the linear target material 12 from the bobbin into the target holding unit 10.

The supply unit 40 may supply the molten target material 12 to the holding surface 17. For example, the supply unit 40 may supply the molten target material 12 to the holding surface 17 using the debris shield 62. The debris shield 62 is disposed in the vicinity of the supply unit 40 so as to cover the supply unit 40. The debris shield 62 is exposed to a temperature higher than or equal to the melting point of the target material 12. As described above, the debris shield 62 may be set to a temperature higher than or equal to the melting point of the target material 12, by the radiation heat at the target holding unit 10 and the target material 12 in the target holding unit 10. The temperature of the debris shield 62 may be adjusted to a temperature higher than or equal to the melting point of the target material 12 by a heating member, such as a heater.

The supply unit 40 may melt a solid target material 12q by making contact with the debris shield 62 or the like, and then be supplied into the target holding unit 10. For example, the target material 12 melted by the debris shield 62 falls to the bottom surface 15, and reaches the inner peripheral surface 16 by the centrifugal force. This negates the need to bring a solid target material 12q into contact with the target material 12 of the holding surface 17. Accordingly, the temperature of the target material 12 of the holding surface 17 can be prevented from decreasing. This disturbance of the surface state of the target material 12 due to vibrations and the like can be prevented.

The cover part 60 includes the debris shields 61 and 62 and a debris cover 65. Note that the cover part 60 does not necessarily include all the debris shields 61 and 62 and the debris cover 65. The cover part 60 may include at least one of the debris shields 61 and 62 and the debris cover 65.

The debris cover 65 is disposed so as to cover the target holding unit 10. For example, the debris cover 65 covers the opening on the +Z axis direction side of the target holding unit 10. Note that the debris cover 65 has an opening formed to extract the excitation light LR and the EUV light LE. The debris cover 65 prevents debris scattering at the same time of formation of the plasma 11 from adhering to a collector mirror and the like. The temperature of the debris cover 65 may be adjusted to a temperature higher than or equal to the melting point of the target material 12. Accordingly, the debris can be re-melted and reused as the target material 12.

The debris shield 61 is disposed so as to cover the position where the plasma 11 is formed. The debris shield 62 is disposed so as to cover the supply unit 40. The debris shield 62 may include a portion disposed on the line extending from the rotational axis R of the target holding unit 10 to the holding surface 17. That is, the debris shield 62 may include a moving radius portion. Accordingly, the debris shield 62 can supply the molten target material 12 to the holding surface 17 by the centrifugal force. At least one of the debris shield 61 and the debris shield 62 may be attached to the debris cover 65.

The output optical system 70 extracts the light L0 generated by irradiating the target material 12 with the excitation light LR, from the light source apparatus 1. The output optical system 70 includes, for example, an optical member 71. The optical member 71 includes, for example, a collector mirror. Note that the optical member 71 is not limited to the collector mirror, and may be a second collector mirror (not shown) that further reflects the light L0 reflected by the collector mirror, as long as it is an optical member that extracts the light L0 generated by irradiating the target material 12 with the excitation light LR.

The optical member 71 reflects the light L0 generated from the target material 12 by irradiation with the excitation light LR. The optical member 71 reflects, for example, EUV light LE generated by irradiation with the excitation light LR. That is, the light L0 may include EUV light LE. The EUV light LE is generated from the plasma 11 formed by irradiating the target material 12 with the excitation light LR. The EUV light LE generated from the plasma 11 and reflected by the optical member 71 is emitted, as illumination and/or exposure light, to an optical apparatus such as an inspection apparatus and/or lithography apparatus.

The control unit 80 may control each member of the light source apparatus 1. The control unit 80 is connected to each member of the light source apparatus 1 via communication lines including wireless and wired ones in a state capable of transmitting information. The control unit 80 analyzes, for example, the state information on the target material 12 acquired by the acquisition unit 20. The control unit 80 analyzes output information that includes the intensity, irradiation position and the like of the light L0, such as illumination light, output by the output optical system 70.

The control unit 80 controls the formation state of plasma 11 that includes the intensity, irradiation position and the like of the excitation light LR at the formation unit 30, based on the state information on the target material 12, the output information on the light L0, such as illumination light, and the like. The control unit 80 controls the supply state that includes the temperature, amount of supply and the like of the target material 12 at the supply unit 40, based on the state information, the output information and the like. The control unit 80 controls the temperature and the like of the cover part 60, based on the state information, the output information and the like.

Next, effects of this embodiment will be described. In the light source apparatus 1 according to this embodiment, the target holding unit 10 has the groove H1 having a cross-sectional shape in which the width and the like of the target material 12 varies in accordance with the amount of the target material 12. The groove H1 includes the first region H11, the second region H12, and the third region H13 having depths different from one another. Accordingly, the acquisition unit 20 can easily acquire the amount of the target material 12 based on the region in which the target material 12 occupies the holding surface 17.

Further, the processing unit 22 acquires the amount of the target material 12, whereby it is possible to reduce depletion of the target material 12.

Further, the amount of the target material 12 is monitored and acquired by the acquisition unit 20, whereby the amount of the target material 12 can be adjusted. Therefore, for example, by increasing the amount of the target material 12, the region in which the target material 12 occupies the holding surface 17 can be widened, and a change in the liquid surface due to a return current of the target material 12 can be reduced. It is therefore possible to reduce the change in the liquid surface due to the return current.

### Second Embodiment

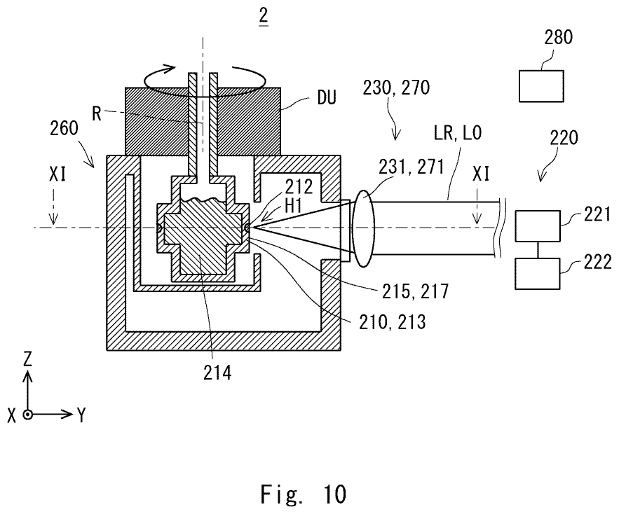

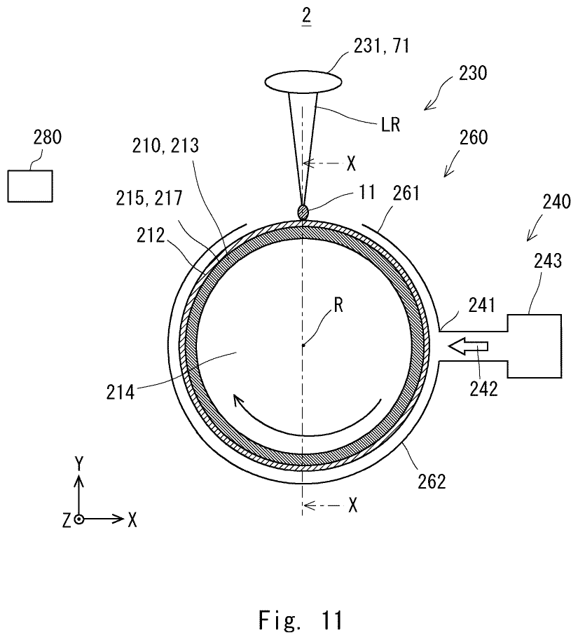

Next, a light source apparatus 2 according to a second embodiment will be described. FIG. 10 is a sectional view showing an example of the light source apparatus 2 according to the second embodiment, and shows a cross section taken along the line X-X of FIG. 11. FIG. 11 is a sectional view showing an example of the light source apparatus 2 according to the second embodiment, and shows a cross section taken along the line XI-XI of FIG. 10.

As shown in FIGS. 10 and 11, the light source apparatus 2 includes a target holding unit 210, an acquisition unit 220, and a processing unit 222. Note that the light source apparatus 2 may further include, besides the target holding unit 210, the acquisition unit 220, and the processing unit 222, a drive unit DU, a formation unit 230, a supply unit 240, a cover part 260, an output optical system 270, and a control unit 280.

The target holding unit 210 holds a target material 212. The target holding unit 210 includes a cylindrical (cylinder-shaped) drum 213. The inside of the drum 213 is filled with coolant 214, such as liquid nitrogen. The target holding unit 210 holds the target material 212 by fixing a solid serving as the target material 212, such as frozen xenon (Xe), on an outer peripheral surface 215 of the drum 213. In the present embodiment, a holding surface 217 of the target holding unit 210 includes the outer peripheral surface 215 of the drum 213.

In this embodiment, the outer peripheral surface 215 of the drum 213 that functions as the holding surface 217 may include a groove H1. That is, in this embodiment as well, the holding surface 217 has a groove H1. For example, the groove H1 is formed along the intersection of the outer peripheral surface 215 with the surface orthogonal to the rotational axis R. The groove H1 is formed concave in the outer peripheral surface 215 in a direction of approaching the rotational axis R. When the outer peripheral surface 215 has the groove H1, the target material 212 may be held in the groove H1.

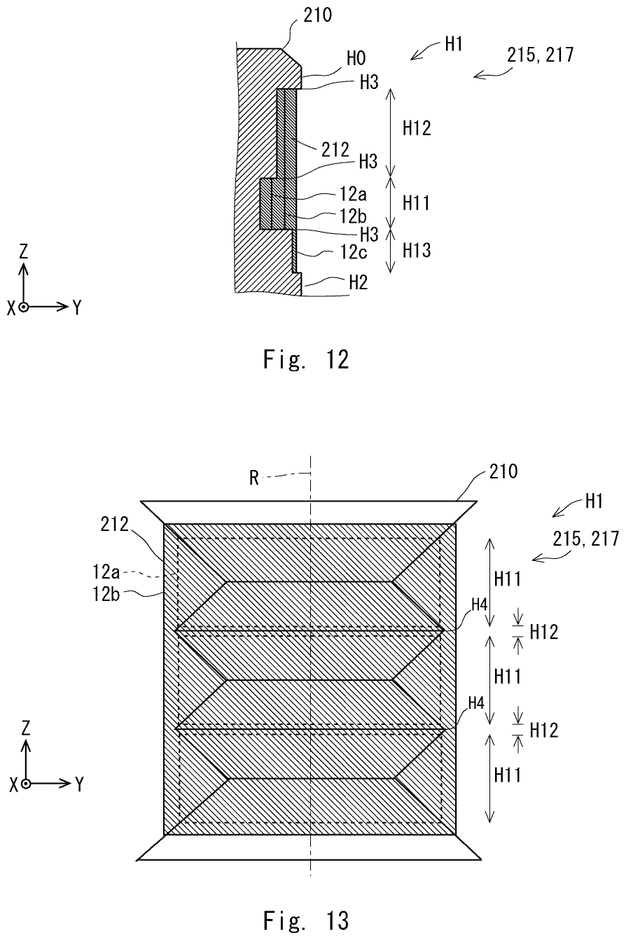

FIG. 12 is a sectional view showing an example of the groove H1 of the target holding unit 210 in the light source apparatus 2 according to the second embodiment. As shown in FIG. 12, in this embodiment as well, the groove H1 may include a first region H11, a second region H12, and a third region H13. Accordingly, the holding surface 217 may include a first region H11, a second region H12, and a third region H13. Therefore, the first region H11, the second region H12, and the third region H13 are formed on the outer peripheral surface 215 of the drum 213. Each part of the first region H11, the second region H12, and the third region H13 in the groove H1 may have depths different from one another. Note that each part of the first region H11, the second region H12, and the third region H13 may be disposed at different depths with reference to a cylindrical surface H0 on which the groove H1 is formed in a direction of approaching the rotational axis R.

As described above, when a distance from the cylindrical surface H0 on which the groove H1 is formed to the rotational axis R is defined to be a reference distance, an absolute value of a difference between the reference distance and the distance from each part of the first region H11, the second region H12, and the third region H13 to the rotational axis R is called a depth. Further, the depth of each part of the first region H11, the second region H12, and the third region H13 is also the distance from the predetermined surface to each part in the direction orthogonal to the direction of the surface of the target material 12. In this embodiment, the length obtained by subtracting the distance between each part of the first region H11, the second region H12, and the third region H13, and the rotational axis R from the reference distance is a depth of each part. In this embodiment, the distance from the rotational axis R to the first region H11 is shorter than that to the second region H12. The distance to the second region H12 is shorter than that to the third region H13. Furthermore, the distance to the third region H13 is shorter than that to the cylindrical surface H0, which may be the region farthest from the rotational axis R.

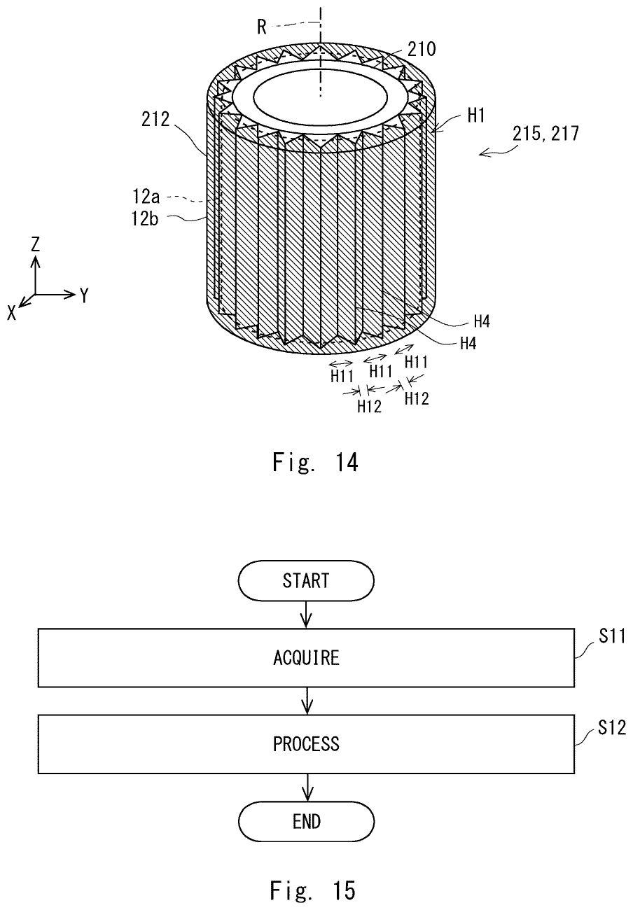

FIG. 13 is a side view showing an example of another groove H1 of the target holding unit 210 in the light source apparatus 2 according to the second embodiment. FIG. 14 is a perspective view showing an example of another groove H1 of the target holding unit 210 in the light source apparatus 2 according to the second embodiment. As shown in FIG. 13, in this embodiment, the first region H11 and the second region H12 may each include a part extending along the rotational direction around the rotational axis R. The holding surface 217 may include a plurality of grooves H1. The plurality of grooves H1 are aligned in the direction of the rotational axis R. Between the grooves H1 there are projecting parts H4 where slopes of the grooves H1 on both sides are connected together. Accordingly, the cross section along the rotational axis R on the side surface of the drum 213 is jagged.

Each of the grooves H1 includes the first region H11. The second region H12 is disposed between the first regions H11 vertically adjacent to each other. Therefore, the second region H12 of the drum 213 may form the aforementioned projecting part H4. When the projecting part H4 as the second region H12 is projected on the surface of the target material 212, the target material 212 is held in the first region H11 and is not held in the second region H12. In this case, the amount of the target material 212 is a first amount 12a. When the projecting part H4 is covered with the target material 212 and hidden by the target material 212, the target material 212 is held in the first region H11 and the second region H12. Therefore, in this case, the amount of the target material 212 is a second amount 12b.

When, for example, the target material 212 is held in the first region H11 and is not held in the second region H12, the amount of supply of gas 242 of the target material 212 by the supply unit 240 is increased. Accordingly, it is possible to reduce exposure of the projecting parts H4, which are jagged tops.

As shown in FIG. 14, the first region H11 and the second region H12 may each have a part extending in the direction of the rotational axis R. The holding surface 217 may include a plurality of grooves H1. The plurality of grooves H1 are aligned in the rotational direction of the rotational axis R. Between the grooves H1 there are projecting parts H4 where slopes of the grooves H1 on both sides are connected together. Accordingly, the cross section orthogonal to the rotational axis R on the side surface of the drum 213 is jagged.

Each of the grooves H1 includes the first region H11. The second region H12 is disposed between the first regions H11 adjacent to each other in the rotational direction. Therefore, the second region H12 of the drum 213 may form the aforementioned projecting part H4. When the projecting part H4 as the second region H12 is projected on the surface of the target material 212, the target material 212 is held in the first region H11 and is not held in the second region H12. In this case, the amount of the target material 212 is the first amount 12a. When the projecting part H4 is covered with the target material 212 and hidden by the target material 212, the target material 212 is held in the first region H11 and the second region H12. Therefore, in this case, the amount of the target material 212 is the second amount 12b.

When, for example, the target material 212 is held in the first region H11 and is not held in the second region H12, the target material 12 is disposed in the rotational direction of the rotational axis R in a distributed manner on the outer peripheral surface 215 of the drum 213. In such a case, the amount of supply of the gas 242 of the target material 212 by the supply unit 240 is increased. Additionally or alternatively, the excitation light LR is emitted in such a way that the rotation cycle of the first region H11 passing through the irradiation position and the cycle of the emission of excitation light LR are synchronized with each other so that the target material 212 in the first region H11 is irradiated with the excitation light LR.

The drive unit DU drives the target holding unit 210 to move the holding surface 217. The drive unit DU rotates the target holding unit 210 around the rotational axis R.

The acquisition unit 220 is disposed on the +Y axis direction side of the target holding unit 210. The acquisition unit 220 acquires state information of the holding surface 217 of the target holding unit 210. For example, the acquisition unit 220 may include a camera 221. The acquisition unit 220 acquires, as the state information of the holding surface 217 of the target holding unit 210, image information of the holding surface 217 imaged by the camera 221. The camera 221 images the holding surface 217 of the target holding unit 210 via the condenser lens 231.

The formation unit 230 is disposed on the +Y axis direction side of the target holding unit 210. The formation unit 230 irradiates the target material 212 held on the holding surface 217 on the +Y axis direction side of the target holding unit 210 with excitation light LR traveling in the −Y axis direction. The formation unit 230 focuses excitation light LR via the condenser lens 231.

The supply unit 240 is disposed on the +X axis direction side of the target holding unit 210. The supply unit 240 has a supply port 241. The supply port 241 faces the +X axis direction side of the target holding unit 210. The supply port 241 communicates with a supply source 243 of the gas 242 of the target material 212. The supply source 243 supplies the gas 242 of the target material 212 to the holding surface 217 through the supply port 241. The gas 242 of the target material 212 supplied through the supply port 241 is fixed on the surface of the drum 213, thereby forming the target material 212.

The cover part 260 includes debris shields 261 and 262. The debris shield 261 is disposed so as to cover the holding surface 217 which is between the position where the plasma 11 is formed and the supply port 241. The debris shield 262 is disposed so as to cover the holding surface 217 which is between the supply port 241 and the position where the plasma 11 is formed. The output optical system 270 extracts light L0 such as EUV light LE through an optical member 271.

Like in this embodiment, even when the solid target material 212 is held in the target holding unit 210 such as the cylindrical drum 213, effects similar to those in the first embodiment can be obtained.

Next, a method for controlling the light source apparatuses 1 and 2 will be described. FIG. 15 is a flowchart showing an example of the method for controlling the light source apparatuses 1 and 2 according to the first and second embodiments. As shown in FIG. 15, the method for controlling the light source apparatuses 1 and 2 includes an acquisition step S11 and a processing step S12. While the reference symbols used in the light source apparatus 1 will be used in the following description, the same reference symbols are used in the light source apparatus 2 as well.

In Step S11, state information of the holding surface 17 of the target holding unit 10 including the holding surface 17 that holds the target material 12 for generating light is acquired. Specifically, the acquisition unit 20 acquires state information. For example, the acquisition step S11 may include acquiring image information of the holding surface 17 imaged by the camera 21 as state information.

In Step S12, the amount of the target material 12 is acquired based on the state information. Specifically, the processing unit 22 acquires the amount of the target material 12 based on the state information. For example, the processing step S12 includes acquiring the amount of the target material 12 based on a region in which the target material 12 occupies the holding surface 17 in the state information. Further, the processing step S12 may include acquiring the amount of the target material 12 based on the region in which the target material 12 occupies the holding surface 17 identified in the image information. Further, the processing step S12 may include acquiring the amount of the target material 12 based on the presence or absence of a specific light in the discontinuous part H3 identified in the image information. Further, the processing step S12 may include acquiring the amount of the target material 12 based on the presence or absence of a specific light in the second region H12. It is therefore possible to control the light source apparatus 1.

The embodiments of the present disclosure have thus been described above. However, the present disclosure encompasses appropriate modifications without impairing the object and advantages. Furthermore, the present disclosure is not limited by the embodiments described above. The configurations and components of the first and second embodiments, and the modification example may be combined with each other as appropriate.

The control unit 80 may include the processing unit 22. The processing unit 22 may include the control unit 80. The control unit 280 may include the processing unit 222. The processing unit 222 may include the control unit 80. The processing unit (the processing 22 or the processing unit 222) may be, for example, an information processing device such as a server or a personal computer. The processing unit may further include one or more processors, a memory, a storage device, and a user interface. The storage device stores, as a program, processing to be executed by each configuration of the processing unit. Also, the processor reads the program from the storage device to the memory and executes the program. The processing unit may be configured to execute program instructions causing the one or more processors to acquire an amount of the target material based on the state information. In this manner, the processor realizes the functions of each configuration in the processing unit. The user interface may include input devices such as a keyboard, a mouse, and an image capturing device and output devices such as a display, a printer, and a speaker.

Each configuration included in the processing unit may be realized by dedicated hardware. In addition, some or all of the components may be realized by general-purpose or dedicated circuitries, the processor, or the like, or a combination thereof. These may be configured of a single chip or may be configured of a plurality of chips connected via a bus. Some or all of the components may be realized by a combination of the aforementioned circuitries or the like and the program. Furthermore, a central processing unit (CPU), a graphics processing unit (GPU), a field-programmable gate array (FPGA), a quantum processor (quantum computer control chip), or the like can be used as the processor.

The first and second embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims. The following configuration is also encompassed by the technical though of the embodiments.

### (Supplementary Note 1)

A method for controlling a light source apparatus, the method comprising:
an acquisition step of acquiring state information of a holding surface of a target holding unit having the holding surface that holds a target material for generating light; and
a processing step of acquiring an amount of the target material based on the state information, wherein
the holding surface includes a first region and a second region,
a depth of the first region from a predetermined surface is greater than that of the second region,
the target material is held in the first region when the amount of the target material is a first amount,
the target material is held in the first region and the second region when the amount of the target material is a second amount which is greater than the first amount, and
the processing step comprises acquiring the amount of the target material based on a region in which the target material occupies the holding surface in the state information.

### (Supplementary Note 2)

A light source apparatus comprising:
a target holding unit having a holding surface that holds a target material for generating light;
an acquisition unit that comprises a camera and acquires image information of the holding surface imaged by the camera; and
a processing unit configured to acquire an amount of the target material based on the image information, wherein
the holding surface includes a first region and a second region,
a depth of the first region from a predetermined surface is greater than that of the second region,
the target material is held in the first region when the amount of the target material is a first amount,
the target material is held in the first region and the second region when the amount of the target material is a second amount which is greater than the first amount, and
   the processing unit acquires the amount of the target material based on a region in which the target material occupies the holding surface identified in the image information.

### (Supplementary Note 3)

A method for controlling a light source apparatus, the method comprising:
an acquisition step of acquiring state information of a holding surface of a target holding unit having the holding surface that holds a target material for generating light; and
a processing step of acquiring an amount of the target material based on the state information, wherein
the holding surface includes a first region and a second region,
a depth of the first region from a predetermined surface is greater than that of the second region,
the target material is held in the first region when the amount of the target material is a first amount,
the target material is held in the first region and the second region when the amount of the target material is a second amount which is greater than the first amount,
the acquisition step comprises acquiring image information of the holding surface imaged by a camera as the state information, and
the processing step comprises acquiring the amount of the target material based on a region in which the target material occupies the holding surface identified in the image information.

### (Supplementary Note 4)

A method for controlling a light source apparatus, the method comprising:
an acquisition step of acquiring state information of a holding surface of a target holding unit having the holding surface that holds a target material for generating light; and
a processing step of acquiring an amount of the target material based on the state information, wherein
the holding surface includes a first region and a second region,
a depth of the first region from a predetermined surface is greater than that of the second region,
the target material is held in the first region when the amount of the target material is a first amount,
the target material is held in the first region and the second region when the amount of the target material is a second amount which is greater than the first amount,
the holding surface includes a discontinuous part between the first region and the second region,
the discontinuous part is not covered with the target material when the amount of the target material is the first amount,
the discontinuous part is covered with the target material when the amount of the target material is the second amount,
the acquisition step comprises acquiring image information of the holding surface imaged by a camera as the state information, and
the processing step comprises acquiring the amount of the target material based on the presence or absence of a specific light in the discontinuous part identified in the image information.

### (Supplementary Note 5)

A method for controlling a light source apparatus, the method comprising:
an acquisition step of acquiring state information of a holding surface of a target holding unit having the holding surface that holds a target material for generating light; and
a processing step of acquiring an amount of the target material based on the state information, wherein
the holding surface includes a first region and a second region,
a depth of the first region from a predetermined surface is greater than that of the second region,
the target material is held in the first region when the amount of the target material is a first amount,
the target material is held in the first region and the second region when the amount of the target material is a second amount which is greater than the first amount,
the second region has a tip that is projected,
the acquisition step comprises acquiring image information of the holding surface imaged by a camera as the state information, and
the processing step acquires the amount of the target material based on the presence or absence of a specific light in the second region identified in the image information.
   (Supplementary note 6)

A light source apparatus comprising:
a target holding unit having a holding surface that holds a target material for generating light;
an acquisition unit configured to acquire state information of the holding surface; and
a processing unit including one or more processors configured to execute program instructions causing the one or more processors to acquire an amount of the target material based on the state information, wherein
the holding surface includes a first region and a second region,
a depth of the first region from a predetermined surface is greater than that of the second region,
the target material is held in the first region when the amount of the target material is a first amount,
the target material is held in the first region and the second region when the amount of the target material is a second amount which is greater than the first amount, and
the processing unit acquires the amount of the target material based on a region in which the target material occupies the holding surface in the acquired state information.
   (Supplementary note 7)

A method for controlling a light source apparatus, being executed by one or more processors executing program stored in a memory, the method comprising:
an acquisition step of acquiring, by an acquisition unit, state information of a holding surface of a target holding unit having the holding surface that holds a target material for generating light; and
a processing step of acquiring, by the one or more processors, an amount of the target material based on the state information, wherein
the holding surface includes a first region and a second region,
a depth of the first region from a predetermined surface is greater than that of the second region,
the target material is held in the first region when the amount of the target material is a first amount,
the target material is held in the first region and the second region when the amount of the target material is a second amount which is greater than the first amount, and
the processing step comprises acquiring the amount of the target material based on a region in which the target material occupies the holding surface in the state information.

What is claimed is:

1. A light source apparatus comprising:
a target holding unit having a holding surface that holds a target material for generating light;
an acquisition unit configured to acquire state information of the holding surface; and
a processing unit configured to acquire an amount of the target material based on the state information, wherein
the holding surface includes a first region and a second region,
a depth of the first region from a predetermined surface is greater than that of the second region,
the target material is held in the first region when the amount of the target material is a first amount,
the target material is held in the first region and the second region when the amount of the target material is a second amount which is greater than the first amount, and
the processing unit acquires the amount of the target material based on a region in which the target material occupies the holding surface in the acquired state information.

2. The light source apparatus according to claim 1, wherein
the holding surface further includes a third region,
a depth of the second region from the predetermined surface is greater than that of the third region, and
the target material is held in the first region, the second region, and the third region when the amount of the target material is a third amount which is greater than the second amount.

3. The light source apparatus according to claim 1, wherein the processing unit acquires the amount of the target material based on at least one of a width and an area of a region in which the target material covers the holding surface.

4. The light source apparatus according to claim 1, wherein
the acquisition unit comprises a camera,
the acquisition unit acquires image information of the holding surface imaged by the camera as the state information of the holding surface, and
the processing unit acquires the amount of the target material based on a region in which the target material occupies the holding surface identified in the image information.

5. The light source apparatus according to claim 4, further comprising:
a formation unit comprising a condenser lens that focuses excitation light forming plasma by exciting the target material on the target material, and
the camera images the holding surface via the condenser lens.

6. The light source apparatus according to claim 4, wherein
the acquisition unit further comprises a displacement meter that outputs a displacement amount of a surface position of the target material that covers the holding surface, and
the processing unit acquires the amount of the target material based on the image information and the displacement amount.

7. The light source apparatus according to claim 1, wherein
the holding surface includes a discontinuous part between the first region and the second region,
the discontinuous part is not covered with the target material when the amount of the target material is the first amount, and
the discontinuous part is covered with the target material when the amount of the target material is the second amount.

8. The light source apparatus according to claim 7, wherein the discontinuous part is formed in a corner part where a plane of the holding surface that includes the first region and a plane of the holding surface that includes the second region are connected together.

9. The light source apparatus according to claim 1, wherein
the target holding unit comprises a crucible that rotates around a rotational axis, and
the first region and the second region are formed on an inner peripheral surface of the crucible.

10. The light source apparatus according to claim 9, wherein the first region and the second region each include a part extending along a rotational direction around the rotational axis.

11. The light source apparatus according to claim 9, wherein the first region and the second region each include a part extending along a direction of the rotational axis.

12. The light source apparatus according to claim 1, wherein
the target holding unit comprises a drum that rotates around a rotational axis, and
the first region and the second region are formed on an outer peripheral surface of the drum.

13. The light source apparatus according to claim 12, wherein the first region and the second region each include a part extending along a rotational direction around the rotational axis.

14. The light source apparatus according to claim 12, wherein the first region and the second region each include a part extending along a direction of the rotational axis.

15. A light source apparatus comprising:
a target holding unit having a holding surface that holds a target material for generating light;
an acquisition unit that comprises a camera and acquires image information of the holding surface imaged by the camera; and
a processing unit configured to acquire an amount of the target material based on the image information, wherein
the holding surface includes a first region and a second region,
a depth of the first region from a predetermined surface is greater than that of the second region,
the target material is held in the first region when the amount of the target material is a first amount,
the target material is held in the first region and the second region when the amount of the target material is a second amount which is greater than the first amount,
the holding surface includes a discontinuous part between the first region and the second region,
the discontinuous part is not covered with the target material when the amount of the target material is the first amount,
the discontinuous part is covered with the target material when the amount of the target material is the second amount, and
the processing unit acquires the amount of the target material based on the presence or absence of a specific light in the discontinuous part identified in the image information.

16. A light source apparatus comprising:
a target holding unit having a holding surface that holds a target material for generating light;
an acquisition unit that comprises a camera and acquires image information of the holding surface imaged by the camera; and
a processing unit configured to acquire an amount of the target material based on the image information, wherein
the holding surface includes a first region and a second region,
a depth of the first region from a predetermined surface is greater than that of the second region,
the target material is held in the first region when the amount of the target material is a first amount,
the target material is held in the first region and the second region when the amount of the target material is a second amount which is greater than the first amount,
the second region has a tip that is projected, and
the processing unit acquires the amount of the target material based on the presence or absence of a specific light in the second region identified in the image information.
